(19) United States
(12) Patent Application Publication
(10) Pub. No.: US 2003/0219968 A1
(43) Pub. Date: Nov. 27, 2003

(54) Sacrificial inlay process for improved integration of porous interlevel dielectrics

(76) Inventors: Ercan Adem, Sunnyvale, CA (US); Darrell M. Erb, Los Altos, CA (US)

Correspondence Address: Foley & Lardner, Suite 500, 3000 K Street, N.W., Washington, DC, 20007-8696, US

(21) Appl. No.: 10/021,947

(22) Filed: Dec. 13, 2001

(51) Int. Cl. H01L 21/4763; H01L 21/44

(52) U.S. Cl. 438/622; 438/619; 438/638

(57) ABSTRACT

A nonporous sacrificial layer is used to form conductive elements such as vias or interconnects in an inlay process, resulting in smooth walled structures of the inlaid vias or interconnects and smooth walled structures of any surrounding layers such as barrier layers. After formation of the smooth walled conductive elements, the sacrificial layer is removed and replaced with a porous dielectric, resulting in desirable porous low-k dielectric structures integrated with the smooth walled conductive elements and barrier materials.

### FIELD OF THE INVENTION

Embodiments of the present invention pertain to semiconductor fabrication, and in particular to porous interlevel dielectric layers.

### BACKGROUND TECHNOLOGY

Integrated circuits (ICs) are manufactured by forming discrete semiconductor devices such as MOSFETS and bipolar junction transistors on the surface of a silicon wafer, and then forming a metal wiring network that connects the devices to create circuits. The wiring network is composed of individual metal wirings called interconnects that are connected to devices on the wafer by vertical contacts and are connected to other interconnects by vertical vias. A typical wiring network employs multiple levels of interconnects and vias.

The performance of integrated circuits is determined in large part by the conductivity and capacitance of the wiring network. Copper has recently been adopted as the preferred metal for wiring networks because of its low resistivity compared to other conventional metals. To address capacitance issues, low dielectric constant (“low-k”) materials have been developed for use as interlevel dielectrics surrounding the wiring elements to replace the conventional silicon oxide interlevel dielectric. Conventional low-k materials are typically spin-on organic compounds with a dielectric constant of less than about 3.5, compared to a dielectric constant of about 7.0 for silicon oxides.

To further improve over the conventional spin-on low-k organics, recent efforts have focused on the development of porous dielectric materials that have a reduced overall dielectric constant by virtue of voids formed within the material. Many of these materials are formed by a spin-on process followed by activation such as by thermal processing to form pores. A first type of such materials comprise compounds that incorporate a thermally degradable “porogen” material within a host thermosetting matrix. Upon heating, the matrix material crosslinks, and the porogen undergoes phase separation from the matrix to form nanoscopic domains. Subsequent heating causes porogen decomposition and diffusion of volatile by-products out of the matrix. Dow Chemical's porous SiLK product is an example of an organic porogen-type porous low-k dielectric, while IBM's DendriGlass product is a silicon compound comprising a blend of organosilicates with a polymeric porogen. A variety of other types of porous spin-on dielectrics are also available. Schumacher's MesoELK product yields pores through a self-assembly process. Dow Corning's XLK series of resins employs a high boiling point solvent as a porogen. Honeywell's Nanoglass porous silica films are prepared by the solgel technique, in which an aqueous solution of silica is induced to form a wet gel arranged in an open pore structure. In addition to these spin-on materials, a number of CVD porous dielectrics are being developed. Further information regarding the compositions and properties of various porous dielectric materials is provided in “Designing Porous Low-k Dielectrics,” Semiconductor International, May 2001, and “Industry Divides on Low-k Dielectric Choices,” Semiconductor Inernational, May 2001.

While porous interlevel dielectrics offer the potential for significant reduction of capacitance effects in wiring networks, the integration of porous materials with conventional processing techniques entails a number of problems. For example, conventional copper via and interconnect structures are formed by damascene or dual damascene processes in which the copper is deposited in trenches formed in a previously deposited interlevel dielectric material. In the case of conventional nonporous dielectrics, these trenches have generally smooth surfaces. However, the use of the same techniques with porous materials produces rough trench surfaces having open pores. The open pores make it difficult to achieve continuous coverage by barrier materials, which leads to diffusion of copper into the surrounding dielectric and resultant shorting problems. Similar coverage problems occur with seed layer materials, resulting in discontinuities in deposition of bulk conductive material and increased resistance. Rough sidewalls also produce scattering of electrons that further increases resistance.

Consequently, there is a need for improved techniques for integrating porous interlevel dielectrics with copper wiring networks so that the aforementioned disadvantages of rough sidewalls are avoided.

### SUMMARY OF THE DISCLOSURE

In accordance with embodiments of the present invention, form conductive elements such as vias or interconnects are formed in a sacrificial layer by an inlay process. After formation of the inlaid conductive elements, the sacrificial material is removed and replaced with porous dielectric. Thus the wiring elements are integrated with porous dielectric in a manner that avoids the aforementioned disadvantages.

Embodiments of the invention may therefore pertain to a method for forming a wiring network of an integrated circuit. A substrate that comprises a first conductive element is provided. A sacrificial layer is then formed over the substrate. The sacrificial layer may comprise a single layer of material or multiple layers of materials. At least a portion of a second conductive element is then inlaid in the sacrificial layer in contact with the first conductive element. The portion inlaid may comprise the entire second conductive element, or may include only a portion of the second conductive element such as a bulk conductive core portion. At least a portion of the sacrificial layer surrounding the second conductive element is then removed. The portion removed may comprise the entire layer, or only a portion of the layer surrounding in an area of high wiring density or in another area, or only some layers of a multiple layered sacrificial layer. Porous dielectric material is then formed around the second conductive element to serve as an interlevel dielectric. The second conductive element may comprise a barrier layer and a bulk copper material formed in the trench prior to removal of the sacrificial material. The second conductive element may alternatively comprise a bulk copper material formed in the trench prior to removal of the sacrificial material, and a barrier layer deposited on the bulk copper material after removal of the sacrificial material. In a further alternative, the second conductive element may comprise a bulk copper material formed in the trench prior to removal of the sacrificial material, and a barrier layer formed on the bulk copper material by alloying with an alloying element implanted after removal of the sacrificial material.

Further embodiments of the invention may pertain to a wiring network of an integrated circuit. The wiring network comprises a substrate comprising a first conductive element. A second conductive element having smooth walls contacts the first conductive element, and a porous interlevel dielectric is formed on the substrate and the smooth walls of the second conductive element. The second conductive element may comprise a bulk copper material and a continuous layer of barrier material formed on the bulk copper material. The barrier material may comprise a copper alloy.

Other features and advantages of the present invention will become apparent to those skilled in the art from the following drawings and detailed description and from the appended claims.

### DESCRIPTION OF THE DRAWINGS

Preferred embodiments will hereafter be described with reference to the accompanying drawings, wherein like numerals denote like elements, and in which:

FIG. 1 shows a substrate comprising a first conductive element, and a layer of a sacrificial material formed on the substrate;

FIG. 2 shows the structure of FIG. 1 after etching of a trench in the sacrificial material;

FIG. 3 shows the structure of FIG. 2 after formation of a second conductive element in the trench;

FIG. 4 shows the structure of FIG. 3 after removal of the sacrificial material;

FIG. 5 shows the structure of FIG. 4 after formation of a porous interlevel dielectric layer;

FIG. 6 shows the structure of FIG. 2 after formation of bulk copper in the trench;

FIG. 7 shows the structure of FIG. 6 after removal of the sacrificial material;

FIG. 8 shows the structure of FIG. 7 after formation of a barrier layer on the bulk copper;

FIG. 9 shows the structure of FIG. 7 during implantation of an alloying element;

FIG. 10 shows a dual damascene structure inlaid in a sacrificial layer;

FIG. 11 shows the structure of FIG. 10 after the sacrificial layer is replaced by a porous low-k dielectric; and

FIG. 12 shows a method in accordance with embodiments of the invention.

### DETAILED DESCRIPTION OF PREFERRED EMBODIMENTS

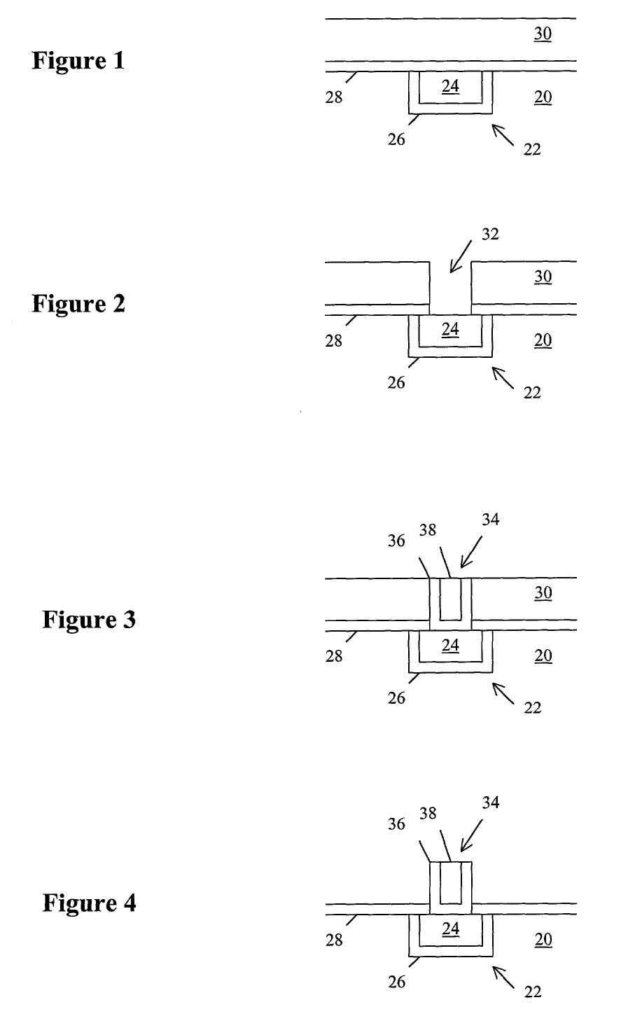

FIGS. 1 through 5 show structures formed at successive stages of a process for forming a conductive element such as a via or interconnect in accordance with a first preferred embodiment of the invention.

FIG. 1 shows a structure comprising a substrate 20 having formed therein a first conductive element 22 comprising a bulk copper conductor 24 encased by a barrier layer 26. The first conductive element may be a via or an interconnect. The barrier layer 26 may be formed of any barrier material such as Ta, TaN, CVD TiNSi, a combination of CVD and PVD materials, or copper alloy comprising an alloying element such as Mg, Ca, Zr or Al. A passivation layer 28 is formed over the substrate. The passivation layer may be formed of any passivation material such as SiN, SiON, or silicon carbide. A sacrificial layer 30 of one or more nonporous materials is formed over the passivation layer 28. The materials of the sacrificial layer 30 typically comprise dielectric materials such as silicon oxide or organic dielectric.

FIG. 2 shows the structure of FIG. 1 after etching to produce a trench 32 in the sacrificial layer 30 and passivation layer 28 to expose the first conductive element within the substrate. The structure of the trench may define the shape of an interconnect or a via. Because the sacrificial material is nonporous, the trench surfaces are essentially smooth since there are no open pores in the side walls.

FIG. 3 shows the structure of FIG. 2 after inlaying of a second conductive element 34 in the trench in contact with the first conductive element 22 by damascene processing. The second conductive element comprises a barrier layer 36 and a bulk copper material 38. The barrier layer prevents diffusion of copper into surrounding materials. The barrier layer 36 may comprise any barrier material such as Ta, TaN, CVD TiNSi, a combination of PVD and CVD materials, or a copper alloy comprising an alloying element such as Mg, Ca, Zr or Al. The bulk copper 38 may be deposited by physical vapor deposition, or by physical vapor deposition of a seed layer followed by electroplating or electroless plating. The bulk copper may include one or more alloying elements such as Sn, In, Zr, Ca, Al, Zn, Cr, La, Hf or Ag. Additional processing such as seed layer enhancement or alloying may also be performed. Deposition of the barrier and bulk materials is followed by planarization such as by CMP to remove excess materials yielding the structure shown in FIG. 3. Because the sacrificial material is nonporous, the barrier layer deposited in the trench forms a continuous layer within the trench.

FIG. 4 shows the structure of FIG. 3 after removing of the sacrificial layer 30 by selective etching that leaves the inlaid second conductive element 34 intact. Where the sacrificial layer material is an organic material of the type CxHyXz, the sacrificial material may be etched using an O₂ or N₂ plasma etch chemistry. Other sacrificial layer dielectrics such as SOG, HSQ or MSQ may be etched with dilute HF. Because the outer barrier layer 36 formed a continuous layer when deposited on the smooth trench walls of the sacrificial layer 30, the second conductive element 34 that remains after removal of the sacrificial material likewise has smooth walls.

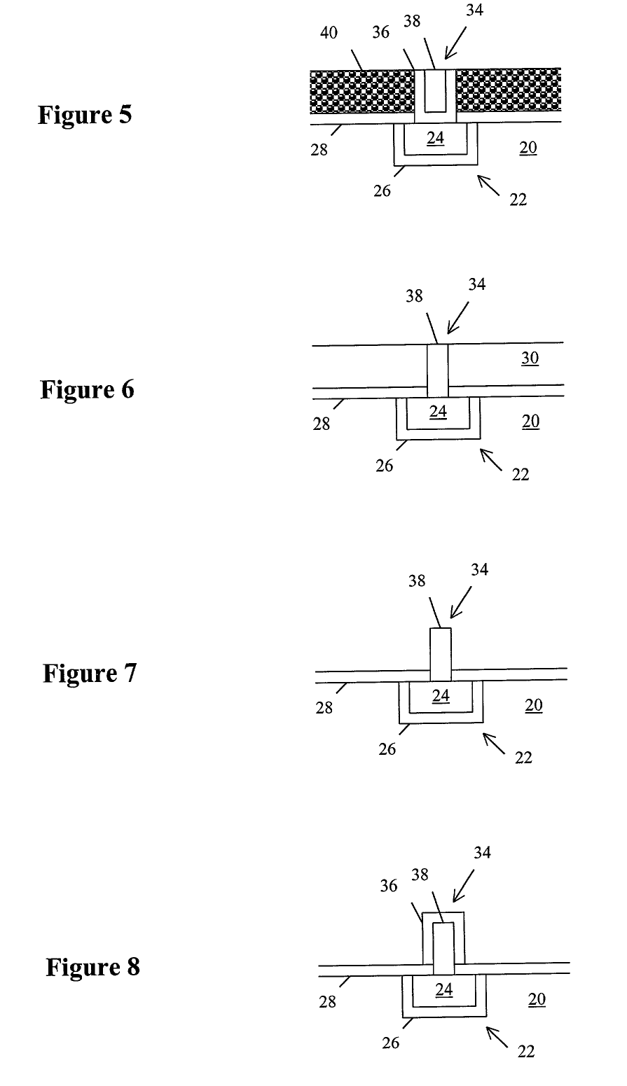

FIG. 5 shows the structure of FIG. 4 after formation of a layer of porous dielectric material 40 on the substrate and around the second conductive element and planarization of the porous dielectric material. The porous dielectric material 40 may be any of those described above, or another material having a porous structure. The porous dielectric material 40 is deposited in any manner, such as by a spin-on method, and is then activated in the manner of the particular material, such as by thermal processing, to form a porous structure. The porous dielectric material 40 is then planarized such as by CMP to yield the structure illustrated in FIG. 5. Because the porous dielectric material 40 is deposited after the structure of the second conductive element 34 has been defined through conventional damascene processing, the presence of open pores at the surfaces of the second conductive element does not affect the structure or electrical characteristics of the second conductive member.

Further processing may be performed on the structure of FIG. 5, such as forming a cap layer on the second conductive element, forming a passivation layer on the porous dielectric or forming additional levels of wiring and interlevel dielectric.

FIGS. 6-8 show alternative processing that may be performed in place of the processing shown in FIGS. 3 and 4 in accordance with a second preferred embodiment. FIG. 6 shows the structure of FIG. 2 after formation in the trench of a bulk copper portion 38 that will comprise an inner portion of a second conductive element 34 in contact with the first conductive element 22. The bulk copper may be deposited in a conventional manner such as by PVD or by PVD deposition of a seed layer followed by electroplating or electroless plating. Unlike the first preferred embodiment, the second preferred embodiment does not form a barrier layer in the trench prior to filling with copper.

FIG. 7 shows the structure of FIG. 6 after removal of the sacrificial layer 30 by selective etching that leaves the inlaid copper structure intact. Because the bulk copper material formed a continuous layer when deposited on the smooth walls of the trench, the bulk copper portion 38 that remains after removal of the sacrificial material has smooth walls.

FIG. 8 shows the structure of FIG. 7 after selective deposition of a continuous barrier layer 36 on the bulk copper portion 38 of the second conductive element 34. Examples of barrier materials are SiC, SiN and SiOC. Because the barrier layer 36 is deposited on the smooth walls of the bulk copper portion 38, the barrier layer 36 is continuous and the walls of the resulting second conductive element 34 are likewise smooth. The process of the second embodiment is preferred in that it provides better step coverage by the barrier layer and also eliminates a layer of barrier material between the bulk copper of the first and second conductive elements and therefore provides better conductivity.

After selective barrier deposition, a layer of porous dielectric is formed over the second conductive element as shown in FIG. 5. Because the porous dielectric material 40 is deposited after the second conductive element 34 is defined, the presence of open pores at the surfaces of the second conductive element does not affect the structure or electrical characteristics of the second conductive element.

In an alternative to the processing of FIG. 8, a continuous barrier layer may be conformally deposited over the bulk copper portion 38 and the substrate through a nonselective process.

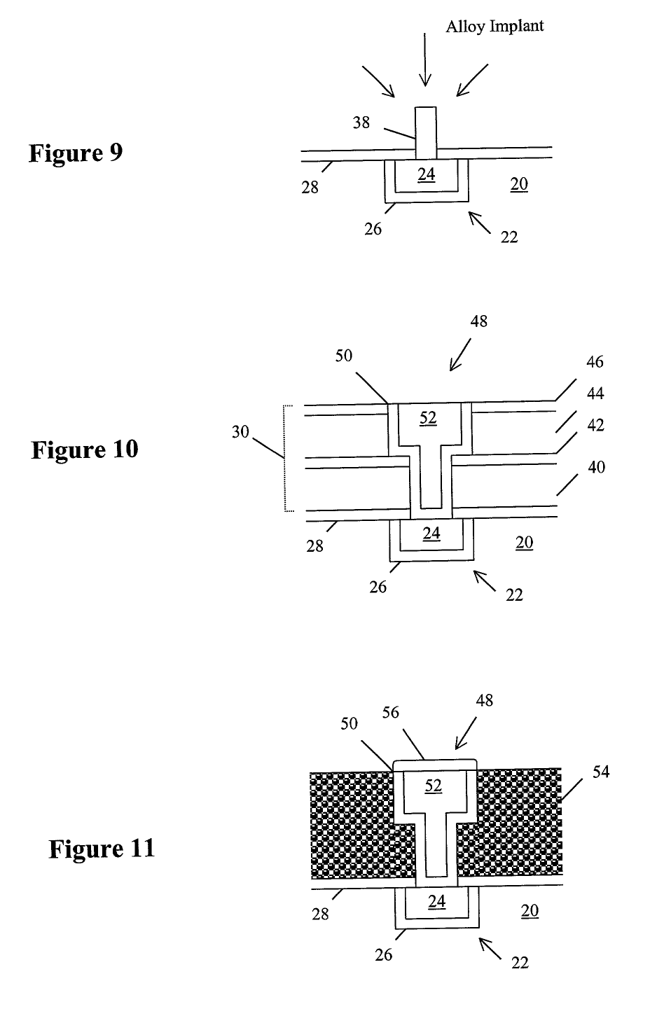

FIG. 9 shows alternative processing that may be performed in place of the processing shown in FIG. 8 in accordance with a third preferred embodiment. FIG. 9 shows a bulk copper portion 38 as shown in FIG. 7, which is subjected to ultra-low energy implantation of one or more alloying elements to implant the alloying element(s) near the surface of the copper. The orientation of the angle of implantation relative to the substrate may be varied so as to fully implant the top and all sides of the bulk copper portion 38. In subsequent processing the copper is annealed to form a copper alloy at the surface of the copper to form a diffusion barrier layer. In the case of alloying elements such as Ca or Zr, it is preferable to mask the substrate before implantation. Alloying elements such as C and B may be implanted without masking the substrate.

While the aforementioned embodiments contemplate complete removal of the sacrificial material from the entire substrate, in alternative embodiments it is not necessary to remove all sacrificial material. In some applications it may be found that removal of only a portion of the sacrificial material will provide an optimal balance of lowered capacitance and processing throughput. In other applications, the sacrificial material may be selectively removed in areas having high wiring density while being left in place in areas with low wiring density. These latter applications may be found desirable where differences in wiring densities will cause uneven accumulation of the spin-on porous low-k dielectric precursor solution, leading to an uneven surface and dishing during subsequent planarization. Selective removal may be accomplished by masking the areas of low wiring density or other areas to be retained during etching of the sacrificial material.

In further embodiments, a sacrificial layer may be used in the formation of a dual damascene inlaid structure. FIG. 10 shows an example of a dual damascene second conductive element 48 that is inlaid in a sacrificial layer 30 comprising a first bulk dielectric material 40, a first stop layer 42 formed over the first bulk dielectric material 40, a second bulk dielectric material 44 formed over the first stop layer 42, and a second stop layer 46 formed over the second bulk dielectric material 44. The dual damascene second conductive element 48 comprises a barrier layer 50 and a bulk copper conductor 52, and is inlaid in a dual damascene trench previously formed in the sacrificial layer 30. In accordance with one embodiment, the sacrificial layer 30 is then removed by etching and replaced with a porous low-k dielectric material 54 to yield the structure illustrated in FIG. 11. In accordance with an alternative embodiment, a portion of the sacrificial layer 30 may be selectively removed in areas of high wiring density and replaced by a porous dielectric material. In accordance with a further alternative embodiment, the second stop layer 46 and second bulk dielectric layer 44 may be completely removed or selectively removed and replaced with porous dielectric, while the first bulk layer 40 and first stop layer 42 are left intact.

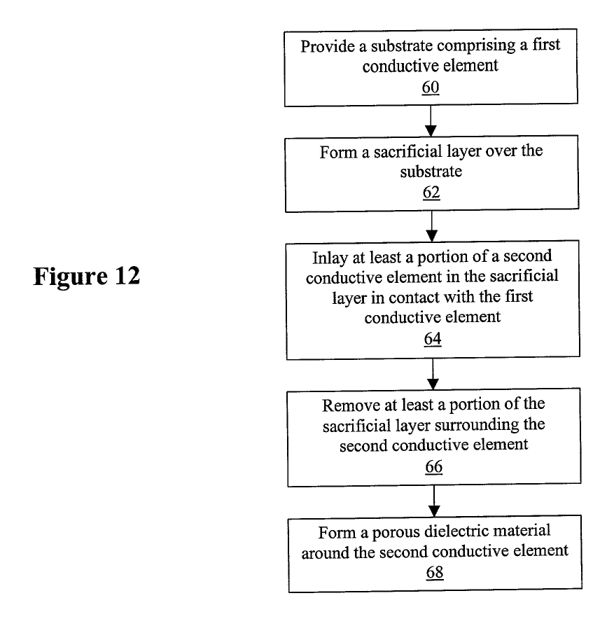

Embodiments of the invention are therefore applicable to a variety of structures in which it is desirable to provide a conductive element having a smooth walled structure, as provided by an inlay process employing a nonporous sacrificial material, while also employing a porous material as a surrounding interlevel dielectric. A basic process in accordance with the aforementioned preferred embodiments and other alternative embodiments is illustrated in FIG. 12. Initially, a substrate is provided (60). The substrate comprises a first conductive element. A sacrificial layer is then formed over the substrate (62). The sacrificial layer may comprise a single layer of material or multiple layers of materials. At least a portion of a second conductive element is then inlaid in the sacrificial layer in electrical contact with the first conductive element (64). The portion inlaid may comprise the entire second conductive element, as in the example of FIG. 3, or may include only a portion of the second conductive element, as in the example of FIG. 6. At least a portion of the sacrificial layer surrounding the second conductive element is then removed (66). The portion removed may comprise the entire layer, or only a portion of the layer that surrounds an area of high wiring density or in another area, or only some of multiple layers that comprise the sacrificial layer as discussed above in regard to the dual damascene case. Porous dielectric material is then formed around the second conductive element (68) to serve as an interlevel dielectric.

It will be apparent to those having ordinary skill in the art that the tasks described in the above processes are not necessarily exclusive of other tasks, but rather that further tasks may be incorporated into the above processes in accordance with the particular structures to be formed. For example, intermediate processing tasks such as seed layer formation, seed layer enhancement, alloying such as by implantation or diffusion, annealing, cleaning, formation and stripping of oxidation layers, formation and removal of passivation layers or protective layers between processing tasks, formation and removal of photoresist masks and other masking layers, as well as other tasks, may be performed along with the tasks specifically described above. Further, the process need not be performed on an entire substrate such as an entire wafer, but rather may be performed selectively on sections of the substrate. Thus, while the embodiments illustrated in the figures and described above are presently preferred, it should be understood that these embodiments are offered by way of example only. The invention is not limited to a particular embodiment, but extends to various modifications, combinations, and permutations that fall within the scope and spirit of the appended claims.

What is claimed is:

1. A method for forming a wiring network of an integrated circuit, comprising:
providing a substrate comprising a first conductive element;
forming a sacrificial layer over the substrate;
inlaying at least a portion of a second conductive element in the sacrificial layer in electrical contact with the first conductive element;
removing at least a portion of the sacrificial layer surrounding the second conductive element; and
forming a porous dielectric material around the second conductive element.

2. The method claimed in claim 1, wherein the second conductive element comprises:
a bulk copper material; and
a continuous layer of barrier material formed on the bulk copper material.

3. The method claimed in claim 1, wherein the sacrificial material comprises a silicon oxide.

4. The method claimed in claim 1, wherein the sacrificial material comprises an organic dielectric.

5. The method claimed in claim 1, wherein the porous dielectric comprises a porous organic dielectric.

6. The method claimed in claim 1, wherein the porous dielectric comprises a porous silicon compound.

7. The method claimed in claim 1, wherein the first conductive element comprises a copper interconnect and the second conductive element comprises a copper via.

8. The method claimed in claim 1, wherein the first conductive element comprises a copper via and the second conductive element comprises a copper interconnect.

9. The method claimed in claim 1, wherein the provided substrate further comprises a passivation layer overlying the first conductive element, and
wherein said inlaying comprises inlaying the second conductive element in the passivation layer.

10. The method claimed in claim 1, wherein forming the second conductive element comprises:
forming a trench in the sacrificial layer to expose the first conductive element;
forming a layer of a barrier material in the trench in electrical contact with the first conductive element; and
forming bulk copper in the trench.

11. The method claimed in claim 10, wherein said bulk copper comprises an alloying element.

12. The method claimed in claim 1, wherein the at least a portion of the sacrificial layer that is removed is located in an area of high wiring density.

13. The method claimed in claim 1, wherein the second conductive element is a dual damascene structure.

14. The method claimed in claim 1, wherein forming the sacrificial layer comprises:
forming a first bulk dielectric layer on the substrate;
forming a first stop layer on the first bulk dielectric layer;
forming a second bulk dielectric layer on the first stop layer;
forming a second stop layer on the second bulk dielectric layer.

15. The method claimed in claim 14, wherein inlaying at least a portion of the second conductive element comprises a dual damascene process producing a dual damascene second conductive element.

16. The method claimed in claim 1, wherein inlaying at least a portion of the second conductive element comprises:
forming a trench in the sacrificial layer to expose the first conductive element;
forming bulk copper in the trench in electrical contact with the first conductive element;
removing the sacrificial layer; and
forming a layer of a barrier material over the bulk copper.

17. The method claimed in claim 16, wherein said bulk copper comprises an alloying element.

18. The method claimed in claim 1, wherein inlaying at least a portion of the second conductive element comprises:
forming a trench in the sacrificial layer to expose the first conductive element;
forming bulk copper in the trench in contact with the first conductive element;
removing the sacrificial material;
implanting an alloying element into the bulk copper; and
annealing the bulk copper to form a copper alloy diffusion barrier at the surface of the bulk copper.

19. A wiring network of an integrated circuit, comprising:
a substrate comprising a first conductive element;
a second conductive element formed on the substrate and contacting the first conductive element, the second conductive element having smooth walls; and
a porous interlevel dielectric formed over the substrate and in contact with the smooth walls of the second conductive element.

20. The wiring network claimed in claim 19, wherein the second conductive element comprises:
a bulk copper material; and
a continuous layer of barrier material formed on the bulk copper material.

21. The wiring network claimed in claim 20, wherein the layer of barrier material comprises a copper alloy.

22. The wiring network claimed in claim 19, wherein the porous dielectric comprises a porous organic dielectric.

23. The wiring network claimed in claim 19, wherein the porous dielectric comprises a porous silicon compound.

24. The wiring network claimed in claim 19, wherein the first conductive element comprises a copper interconnect and the second conductive element comprises a copper via.

25. The wiring network claimed in claim 19, wherein the first conductive element comprises a copper via and the second conductive element comprises a copper interconnect.

26. The wiring network claimed in claim 19, wherein the substrate further comprises a passivation layer overlying the first conductive element, and
wherein the second conductive element is inlaid in the passivation layer.

27. The wiring network claimed in claim 19, wherein the smooth walled second conductive element is formed by inlaying in a nonporous sacrificial layer.

28. The wiring network claimed in claim 19, wherein the second conductive element is a dual damascene structure.
